(19) United States
(12) Patent Application Publication
(10) Pub. No.: US 2014/0008513 A1
(43) Pub. Date: Jan. 9, 2014

(54) MOUNTING APPARATUS FOR FAN MODULE

(71) Applicants: ZHAN-YANG LI, Shenzhen City (CN); WEN-HU LU, Shenzhen City (CN)

(72) Inventors: ZHAN-YANG LI, Shenzhen City (CN); WEN-HU LU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/567,140

(22) Filed: Aug. 6, 2012

(30) Foreign Application Priority Data
Jul. 9, 2012 (CN) 2012102353808

(51) Int. Cl. H05K 7/20

(52) U.S. Cl. 248/672

(57) ABSTRACT

A mounting apparatus includes a cage, a cover, a mounting member, an operation member, and a resilient member. The cage is adapted to mount the fan module and defines a cutout. The cover is secured to the cage. The mounting member is secured between the cage and the cover. The operation member is slidably mounted to the mounting member and received in the cutout. The resilient member is secured between the operation member and the mounting member. The operation member is slidable between a locked and an unlocked position relative to the cage. When the operation member is in the locked position, the hook extends out of the cutout and is adapted to engage in a latching slot of a chassis. When the operation member is in the unlocked position, the hook is slid back and received in the cutout and is disengaged from the latching slot.

### BACKGROUND

1. Technical Field

The present disclosure relates to mounting apparatuses for fan modules, and particularly to a mounting apparatus for a fan module used in a server.

2. Description of Related Art

One or more fan modules are used for cooling in a computer or a server. Usually, each of the fan modules is secured to a mounting frame, and the mounting frame is secured to a chassis of the computer or the server with screws, which is laborious and time consuming. Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of one embodiment of a mounting apparatus and a fan module.

FIG. 2 is an isometric view of a mounting member of the mounting apparatus of FIG. 1.

FIG. 3 is an isometric view of an operation member of the mounting apparatus of FIG. 1.

FIG. 4 is an assembled, isometric view of a mounting assembly of the mounting apparatus of FIG. 1.

FIG. 5 is an isometric view of an assembled mounting apparatus of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

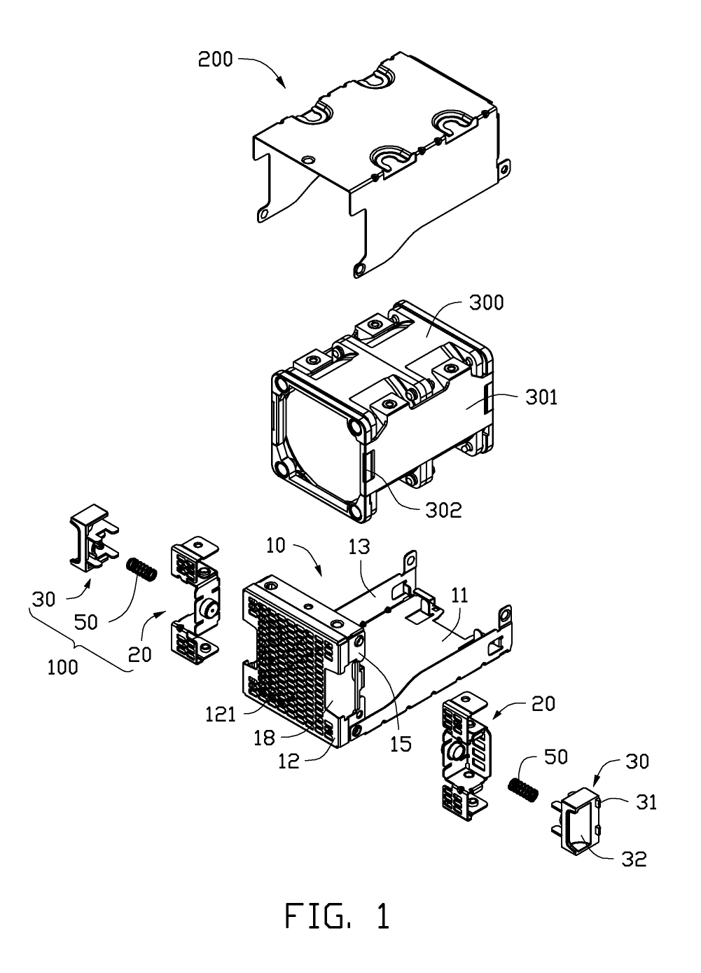

FIG. 1 shows a mounting apparatus for a fan module 300 in accordance with an embodiment. The mounting apparatus includes a cage 10, a cover 200, and two mounting assembles 100.

The cage 10 includes a bottom plate 11, a side plate 12, and two mounting plates 13 extending from two opposite edges of the bottom plate 11. In one embodiment, the bottom plate 11 is substantially perpendicular to the side plate 12 and the two mounting plates 13. The side plate 12 is substantially perpendicular to the two mounting plates 13. A flange 15 extends from each of two opposite edges of the side plate 12 and is substantially parallel to the two mounting plates 13. The flange 15 is riveted with the mounting plate 13. A cutout 18 is defined in the flange 15 and extends to the side plate 12. The side plate 12 defines a plurality of ventilation holes 121.

The cover 200 can be secured to the cage 10 and receives the fan module 300 positioned between the cover 200 and the cage 10.

Each mounting assembly 100 includes a mounting member 20, an operation member 30, and a resilient member 50.

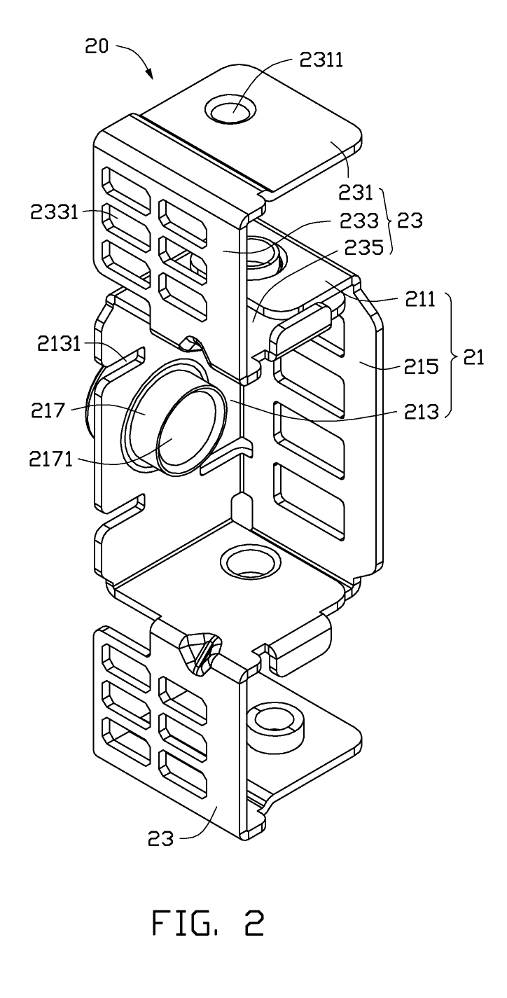

FIG. 2 shows the mounting member 20 including a receiving portion 21 and two mounting portions 23 secured to each of two opposite ends of the receiving portion 21. The receiving portion 21 includes two first connection pieces 211, an installation piece 213, and a limiting piece 215. The installation piece 213 and the limiting piece 215 are located between the two first connection pieces 211 and connected to adjacent two edges of each first connection piece 211. In one embodiment, the two first connection pieces 211 are substantially parallel to each other, the installation piece 213 is substantially perpendicular to the limiting piece 215, the installation piece 213 and the limiting piece 215 are substantially perpendicular to the two first connection pieces 211. The installation piece 213 defines a plurality of installation slots 2131. In one embodiment, an extending direction of each installation slot 2131 is substantially perpendicular to the limiting piece 215. A protruding post 217 is located on the installation piece 213. The protruding post 217 defines an installation hole 2171. Each mounting portion 23 includes a mounting piece 231, a connection piece 233, and a second connection piece 235. In one embodiment, the mounting piece 231 is substantially parallel to the second connection piece 235, the connection piece 233 is substantially perpendicular to the mounting piece 231 and the second connection piece 235. The connection piece 233 defines a plurality of air outlets 2331. The mounting piece 231 defines a mounting hole 2311. The second connection piece 235 is secured to the first connection piece 211 and substantially parallel to the first connection piece 211. The second connection pieces 235 of the two mounting portions 23 are located between the two first connection pieces 211.

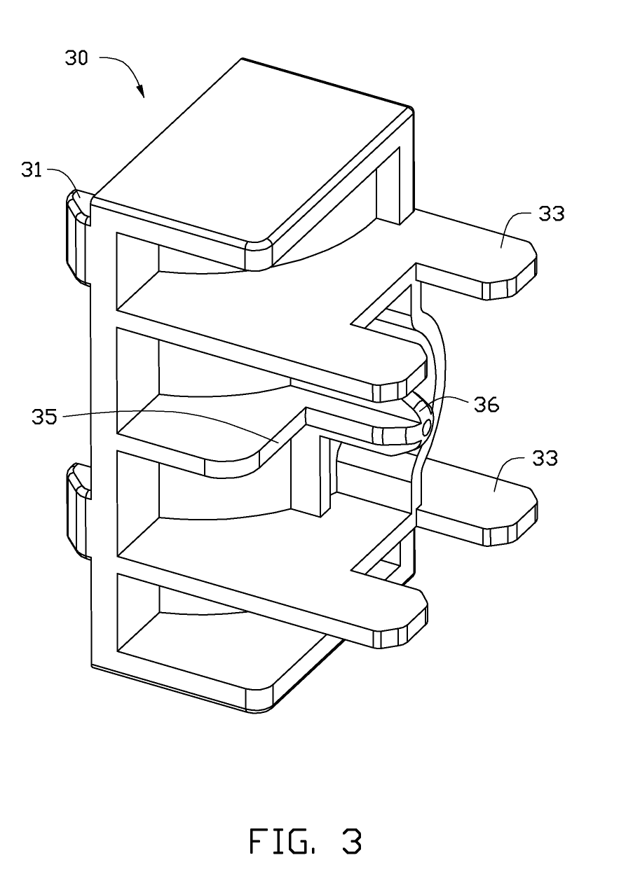

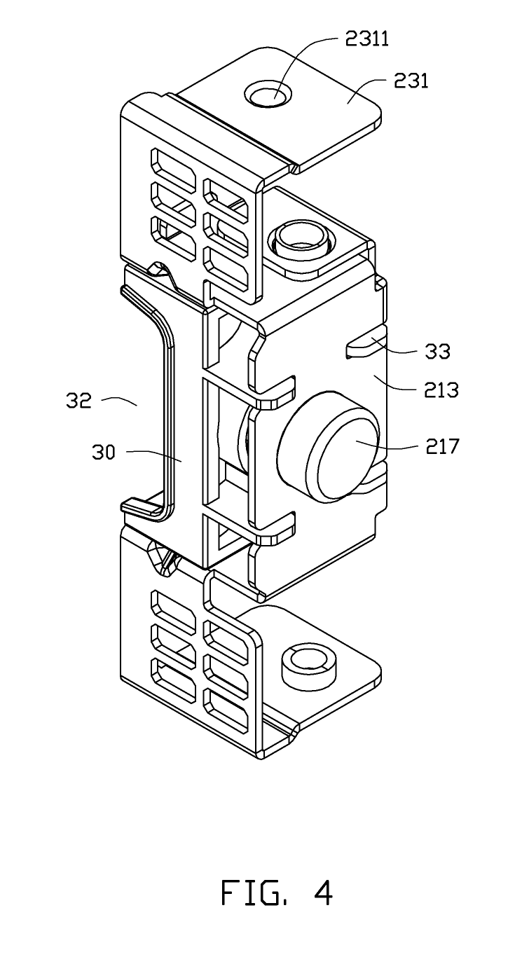

FIG. 3 shows the operation member 30 includes at least one hook 31 and defines an access portion 32 (shown as in FIG. 1 and FIG. 4). The at least hook 31 is capable of engaging in a latching slot of a chassis of a computer or a server (not shown), so as to engage the fan module 300 with the chassis. The access portion 32 is convenient for an operator to operate the operation member 30. The operation member 30 further includes a plurality of positioning pieces 33, a plurality of connection ribs 35, and an inserting portion 36 connected to the plurality of connection ribs 35.

The resilient member 50 can be secured between the operation member 30 and the mounting member 20. In one embodiment, the resilient member 50 is a compression spring.

The mounting apparatus further includes two sidewalls 301 secured to two opposite sides of the fan module 300. Each sidewall 301 defines a limiting slot 302.

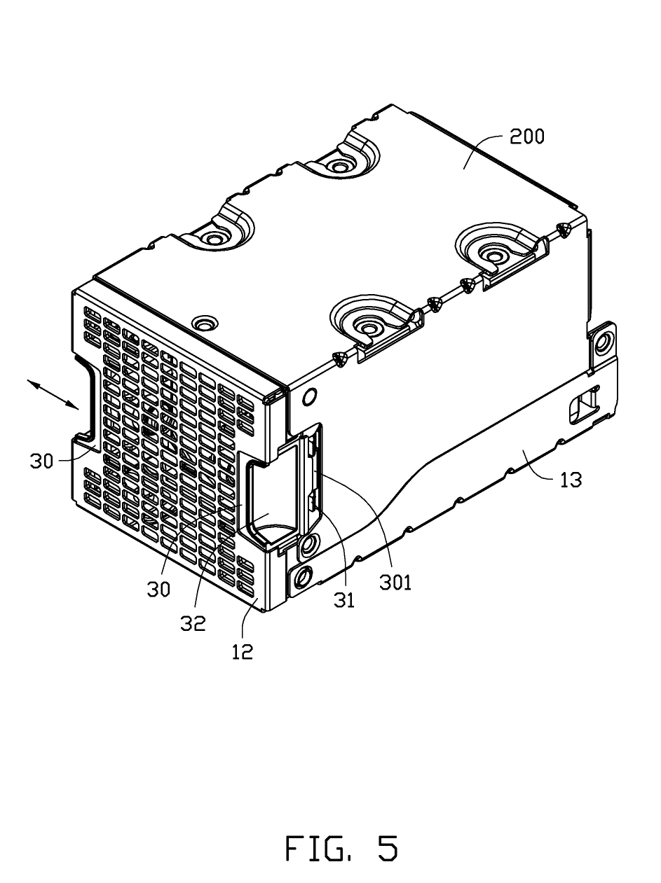

FIG. 4 and FIG. 5 show that, in assembly, a first end of the resilient member 50 is engaged in the installation hole 2171. The operation member 30 is moved towards the mounting member 20 to engage each positioning piece 33 in each installation slot 2131. The inserting portion 36 is received in a second end of the resilient member 50, and the second end of the resilient member 50 abuts the plurality of connection ribs 35. Thus, the mounting assembly 100 is assembled. The fan module 300 and the mounting assembly 100 are placed in the cage 10, and the operation member 30 is received in the cutout 18. The mounting piece 231 of one of the two mounting portions 23 is secured to the bottom plate 11. The hook 31 extends out of the cutout 18 and the limiting slot 302. In this position, the resilient member 50 is in an initial position, and the operation member 30 is located in a locked position. The sidewall 301 abuts the operation member 30, and the operation member 30 is located between the installation piece 213 and the sidewall 301. The cover 200 is secured to the mounting plate 13 and covers the fan module 300. The mounting piece 231 of the other mounting portion 23 is secured to the cover 200.

The two operation members 30 is slidable towards each other relative to the cage 10, to slid the hook 31 back and receive in the cutout 18. The resilient member 30 is elastically deformed. In this position, the two operation members 30 are located in an unlocked position.

In use, each operation members 30 is slid in the unlocked position. The fan module 300 and the mounting apparatus are placed in the chassis, and the hook 31 is aligned with the latching slot. Each operation member 30 is released to rebound the resilient member 50. The resilient member 50 exerts elastic force to push the two operation members 30 to slide away from each other, until each operation member 30 is located in the locked position. In this position, the hook 31 extends out of the limiting slot 302 and engages in the latching slot. Thus, the mounting apparatus secures the fan module 300 to the chassis. In disassembly, the two operation members 30 are slid to the unlocked position, the hook 31 is slid back and received in the limiting slot 302 and disengaged from the latching slot. Thus, the fan module 300 is removed from the chassis.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and the arrangement of parts within the principles of the disclosure, to the full extent indicated by the broad general meaning of the terms in which the appended claims are expressed.

What is claimed is:

1. A mounting apparatus for a fan module, the mounting apparatus comprising:
a cage for mounting the fan module and defining a cutout;
a cover secured to the cage;
a mounting member secured between the cage and the cover;
an operation member slidably mounted to the mounting member and received in the cutout, and the operation member comprising a hook; and
a resilient member secured between the operation member and the mounting member;
wherein the operation member is slidable between a locked position and an unlocked position relative to the cage; when the operation member is in the locked position, the hook extends out of the cutout; when the operation member is in the unlocked position, the hook is slid back and received in the cutout.

2. The mounting apparatus of claim 1, wherein the mounting member comprises a receiving portion and two mounting portions located on two opposite ends of the receiving portion, the two mounting portions are secured to the cover and the cage, and the operation member is received in the receiving portion.

3. The mounting apparatus of claim 2, wherein the receiving portion comprises two first connection pieces, an installation piece, and a limiting piece; the installation piece and the limiting piece are connected between the two first connection pieces; the installation piece defines an installation slot, the operation member comprises a positioning piece; and the position piece is slidably engaged in the installation slot.

4. The mounting apparatus of claim 3, wherein the receiving portion further comprises a protruding post located on the installation piece, and the protruding post defines an installation hole; the operation member comprises an inserting portion; a first end of the resilient member is engaged in the installation slot, and a second end of the resilient member, opposite to the first end, is engaged with the inserting portion.

5. The mounting apparatus of claim 3, wherein the limiting piece is substantially perpendicular to the installation piece, and the limiting piece and the installation piece are substantially perpendicular to the two first connection pieces.

6. The mounting apparatus of claim 3, wherein each of the two mounting portions comprises a mounting piece, a connection piece, and a second connection piece; the mounting piece is secured to the cover or the cage; the second connection piece is secured to one of the two first connection piece; and the connection piece is secured between the mounting piece and the second connection piece.

7. The mounting apparatus of claim 6, wherein the connection piece defines an air outlet; the cage comprises a bottom plate and a side plate connected to the bottom plate, and the side plate defines a ventilation hole; and the air outlet is aligned with the ventilation hole.

8. The mounting apparatus of claim 6, further comprising a sidewall, wherein the sidewall defines a limiting slot, and the sidewall is adapted to be secured to the fan module;
the operation member is located between the installation piece and the sidewall, to prevent the operation member from sliding out of the cutout by the resilient member.

9. The mounting apparatus of claim 8, wherein when the operation member is in the locked position, the hook extends out of the limiting slot; when the operation member is in the unlocked position, the hook is slid back and received in the limiting slot.

10. The mounting apparatus of claim 1, wherein the operation member defines a recess portion for a user to slide the operation member.

11. A mounting apparatus for a fan module, the mounting apparatus comprising:
a cage for mounting the fan module;
a cover secured to the cage;
a sidewall adapted to be secured to the fan module and defining a limiting slot;
a mounting member secured between the cage and the cover;
an operation member slidably mounted to the mounting member and located between the mounting member and the sidewall, and the operation member comprising a hook; and
a resilient member secured between the operation member and the mounting member;
wherein the operation member is slidable between an unlocked position and a locked position relative to the cage; when the operation member is in the unlocked position, the hook is received in the limiting slot, and the resilient member is elastically deformed; when the operation member is in the locked position, the resilient member rebounds, and the hook is slid out of the limiting slot.

12. The mounting apparatus of claim 11, wherein the cage defines a cutout, the operation member is slidably received in the cutout.

13. The mounting apparatus of claim 12, wherein when the operation member is in the locked position, the hook extends out of the cutout; when the operation member is in the unlocked position, the hook is slid back and received in the cutout.

14. The mounting apparatus of claim 11, wherein the mounting member comprises a receiving portion and two mounting portions located on two opposite ends of the receiving portion, the two mounting portions are secured to the cover and the cage, and the operation member is received in the receiving portion.

15. The mounting apparatus of claim 14, wherein the receiving portion comprises two first connection pieces, an installation piece, and a limiting piece; the installation piece and the limiting piece are connected between the two first connection pieces; the installation piece defines an installation slot, the operation member comprises a positioning piece; and
the position piece is slidably engaged in the installation slot.

16. The mounting apparatus of claim 15, wherein the receiving portion further comprises a protruding post located on the installation piece, and the protruding post defines an installation hole; the operation member comprises an inserting portion; a first end of the resilient member is engaged in the installation slot, and a second end of the resilient member, opposite to the first end, is engaged with the inserting portion.

17. The mounting apparatus of claim 15, wherein the limiting piece is substantially perpendicular to the installation piece, and the limiting piece and the installation piece are substantially perpendicular to the two first connection pieces.

18. The mounting apparatus of claim 15, wherein each of the two mounting portions comprises a mounting piece, a connection piece, and a second connection piece; the mounting piece is secured to the cover or the cage; the second connection piece is secured to one of the two first connection piece; and the connection piece is secured between the mounting piece and the second connection piece.

19. The mounting apparatus of claim 18, wherein the connection piece defines an air outlet; the cage comprises a bottom plate and a side plate connected to the bottom plate, and the side plate defines a ventilation hole; and the air outlet is aligned with the ventilation hole.

20. The mounting apparatus of claim 11, wherein the operation member defines a recess portion for a user to slide the operation member.
